(19) United States
(12) Patent Application Publication
(10) Pub. No.: US 2010/0176441 A1
(43) Pub. Date: Jul. 15, 2010

(54) SEMICONDUCTOR MEMORY DEVICE AND MANUFACTURING METHOD THEREFOR

(75) Inventor: Yoshihiro Hirota, Hyogo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: TOKYO ELECTRON LIMITED, Tokyo (JP)

(21) Appl. No.: 12/663,361

(22) PCT Filed: Jun. 6, 2008
(86) PCT No.: PCT/JP08/60812

§ 371 Date: Jan. 14, 2010

(30) Foreign Application Priority Data
Jun. 7, 2007 (JP) 2007-151265

(51) Int. Cl. H01L 29/792; H01L 21/336

(52) U.S. Cl. 257/324; 438/270; 257/E29.309; 257/E29.262; 257/E21.423

(57) ABSTRACT

In a nonvolatile semiconductor memory device of the method which enables a single cell to store more than or equal to 2-bit information, it is possible to prevent wire failure and ensure high operation reliability. The nonvolatile semiconductor memory device 200 includes a trench 203 having a round wall portion 203b; a tunnel oxide film 205, silicon nitride films 207a and 207b as charge trapping regions, a silicon dioxide film 209, a gate electrode 211, and a first source/drain region 213a and a second source/drain region 213b formed on Si substrates 201 arranged to have the gate electrode 211 therebetween.

### FIELD OF THE INVENTION

The present invention relates to a semiconductor device memory and manufacturing method therefor.

### BACKGROUND OF THE INVENTION

As for a nonvolatile semiconductor memory device represented by an electrically rewritable EEPROM (Electrically Erasable and Programmable ROM) or a flash EEPROM, there is known one having a structure referred to as a SONOS (Silicon-Oxide-Nitride-Oxide-Silicon) type or a MONOS (Metal-Oxide-Nitride-Oxide-Silicon) type. In the nonvolatile semiconductor memory device of the above type, information is stored on a silicon nitride film, interposed between silicon dioxide films, serving as a charge trapping layer. That is, in the above-described nonvolatile semiconductor memory device, data is stored by implanting electrons into the silicon nitride film serving as the charge trapping layer by applying a voltage between a semiconductor substrate (silicon) and a control gate electrode (silicon or metal), or the data is erased by removing the electrons accumulated in the silicon nitride film.

As an example of a technique related to a nonvolatile semiconductor memory device, WO99/007000 (hereinafter, referred to as “Patent Document 1”) discloses a technique which causes a single memory cell to store 2-bit information by accumulating charges in each of two charge trapping regions which are spaced apart from each other in the charge trapping layer, e.g., a silicon nitride (SiN) film inserted into a silicon dioxide (SiO₂) film. In the technique described in Patent Document 1, a source and a drain correspond to the two charge trapping regions which respectively serve as the source and drain alternately, so that writing and reading of information can be performed.

Meanwhile, in order to cope with miniaturization of semiconductor devices, a recess gate transistor having a three-dimensional structure in which a part of a gate electrode is buried in a semiconductor substrate. For example, Japanese Patent Application Publication No. 2007-88148 and its corresponding U.S. Patent Application Publication No. 2007/063270 (hereinafter, referred to as “Patent Document 2”) discloses therein a spherical recess gate transistor manufactured by forming on a silicon substrate a flask-shaped trench having a spherical bottom and burying an electrode material in the trench. This transistor can ensure a sufficiently long effective channel length while reducing the area of the transistor.

Patent Document 1: Japanese Patent Application Publication No. 2001-512290 (e.g., FIG. 2 and the like)

Patent Document 2: Japanese Patent Application Publication No. 2007-88148 (e.g., FIG. 9 and the like)

Along with the recent trend towards high integration of semiconductor devices, the miniaturization of the device structure of the nonvolatile semiconductor memory device is in rapid progress. Since further miniaturization of the device structure is expected in the future, the technique of Patent document 1 is disadvantageous in that a short channel effect occurs and thus it is difficult to distinguish a source and a drain. In such a case, there occurs write failure in which when the writing process is performed by trapping charges in one of the charge trapping regions of the charge trapping layer, charges may also be trapped in the other charge trapping region.

### SUMMARY OF THE INVENTION

The present invention has been made in consideration of the above-described problems, and has an object to ensure high operation reliability by preventing write failure in a nonvolatile semiconductor memory device which causes a single memory cell to store more than or equal to 2-bit information.

In accordance with a first aspect of the present invention, there is provided a semiconductor memory device including: a semiconductor layer; a trench formed on the semiconductor layer, the trench including a round wall portion having opposite sidewalls with a curvature; a first insulating film formed along a surface of the semiconductor layer which includes an inner wall of the trench; a pair of separately provided charge trapping regions disposed at the round wall portion of the trench to be adjacent to the first insulating film; a gate electrode having a lower portion inserted into the trench of the semiconductor layer; and a first and a second region arranged in the semiconductor layer to have the gate electrode interposed therebetween, the first and the second region having a conductivity type different from a conductivity type of the semiconductor layer.

The above-described device may further include a second insulating layer formed between the gate electrode and the first insulating layer, and between the gate electrode and each of the charge trapping regions.

In the device described above, each of the charge trapping regions may extend upwardly from the round wall portion of the trench.

In the device described above, each of the charge trapping regions may be formed of silicon nitride film.

In the device described above, the gate electrode is made of a metal, each of the charge trapping regions is formed of a silicon nitride film, the first insulating film is formed of a silicon dioxide film or a silicon oxynitride film, and the semiconductor layer is made of a silicon, thereby having an MNOS structure in a transverse direction to the gate electrode inserted into the semiconductor layer.

In the device described above, the MNOS structure may be formed symmetrically with respect to the gate electrode.

Further, the gate electrode is made of polycrystalline silicon or a metal, the second insulating film is formed of a silicon dioxide film or a silicon oxynitride film, each of the charge trapping regions is formed of a silicon nitride film, the first insulating film is formed of a silicon dioxide film or a silicon oxynitride film, and the semiconductor layer is made of a silicon, thereby having a SONOS structure or a MONOS structure in a transverse direction to the gate electrode inserted into the semiconductor layer.

In the device described above, the SONOS structure or the MONOS structure may be formed symmetrically with respect to the gate electrode.

Further, the first insulating film may be a tunnel oxide film.

In accordance with a second aspect of the present invention, there is provided a semiconductor memory device including: a semiconductor layer; a gate electrode having an upper portion protruded from the semiconductor layer and a lower portion inserted into the semiconductor layer; a first insulating film formed along a surface of the semiconductor layer between the semiconductor layer and the gate electrode; a pair of separately provided charge trapping regions disposed between the first insulating film and the gate electrode; and a first and a second source/drain region arranged in the semiconductor layer to have the gate electrode interposed therebetween.

The above-described device may further include a second insulating layer formed between the gate electrode and the first insulating layer, and between the gate electrode and each of and the charge trapping regions.

In the device described above, the silicon nitride film may be formed by using a plasma processing apparatus for generating a plasma by introducing a microwave into a processing chamber by way of a planar antenna member having a plurality of holes and by using a plasma CVD method for depositing a silicon nitride film by supplying a source gas containing a silicon-containing compound and a nitrogen-containing compound into the processing chamber and generating a plasma by the microwave.

In accordance with a third aspect of the present invention, there is provided a method for manufacturing a semiconductor memory device including: forming on a semiconductor layer a trench including a round wall portion having opposite sidewalls with a curvature; forming a first insulating film on a surface of the semiconductor layer which includes an inner surface of the trench; forming a silicon nitride film to cover the first insulating film by a plasma CVD method; etching the silicon nitride film to remove the silicon nitride film formed at a bottom portion of the trench while leaving a pair of separate silicon nitride films on sidewall portions of the trench which include an inside of the round wall portion; forming an electrode film to fill the trench; forming a gate electrode by patterning the electrode film protruded to the outside of the trench; and forming at both sides of the trench formed on the semiconductor layer a first and a second source/drain region having a conductivity type different from a conductivity type of the semiconductor layer due to impurities doped thereinto.

In said etching the silicon nitride film described in the method, only a pair of separate silicon nitride films may remain on the inside of the round wall portion and the silicon nitride film formed on the other portions may be removed.

Further, the method described above may further include forming a second insulating film to cover the first insulating film and the silicon nitride film between said etching the silicon nitride film and said forming an electrode film.

Further, in the method described above, said forming the silicon nitride film may be performed by using a plasma processing apparatus for generating a plasma by introducing a microwave into a processing chamber by way of a planar antenna member having a plurality of holes and by using a plasma CVD method for depositing a silicon nitride film by supplying a source gas containing a silicon-containing compound and a nitrogen-containing compound into the processing chamber and generating a plasma by the microwave.

Further, the silicon nitride film may be formed by using ammonia or nitrogen as the nitrogen-containing compound and silane (SiH₄), disilane (Si₂H₆) or trisilane (Si₃H₈) as the silicon-containing compound.

Further, the silicon nitride film may be formed by generating a plasma by using ammonia as the nitrogen-containing compound and disilane as the silicon-containing compound while setting a flow rate ratio (ammonia flow rate/disilane flow rate) to be in a range of 0.1 to 1000 and a processing pressure to be in a range of 1 to 1333 Pa.

Further, the silicon nitride film may be formed by generating a plasma by using nitrogen as the nitrogen-containing compound and disilane as the silicon-containing compound while setting a flow rate ratio (nitrogen flow rate/disilane flow rate) to be in a range of 0.1 to 5000 and a processing pressure to be in a range of 0.1 to 500 Pa.

Further, a processing temperature in the plasma CVD method may be in a range of 25 to 600° C.

### EFFECTS OF THE INVENTION

In accordance with the semiconductor memory device of the present invention, a pair of charge trapping regions is separately provided, so that it is possible to reduce write failure that occurs when more than or equal to 2-bit information is written and read by a single memory cell and ensure high operation reliability in spite of the miniaturization. Accordingly, a large capacity storage device can be realized by integration of these semiconductor memory devices.

Further, in accordance with the method for manufacturing the semiconductor memory device of the present invention, the semiconductor memory device having the above-described characteristics can be easily manufactured.

### BRIEF DESCRIPTION OF THE DRAWINGS

FIG. 1 is a schematic view of a nonvolatile semiconductor memory device in accordance with a first embodiment of the present invention.

FIG. 2 provides an explanatory view describing an outline of a manufacturing process of the nonvolatile semiconductor memory device shown in FIG. 1.

FIG. 3 illustrates the manufacturing process of the nonvolatile semiconductor memory device shown in FIG. 1.

FIG. 4 illustrates a process following the process shown in FIG. 3.

FIG. 5 illustrates a process following the process shown in FIG. 4.

FIG. 6 illustrates a process following the process shown in FIG. 5.

FIG. 7 illustrates a process following the process shown in FIG. 6.

FIG. 8 illustrates a process following the process shown in FIG. 7.

FIG. 9 illustrates a process following the process shown in FIG. 8.

FIG. 10 provides a schematic cross sectional view illustrating an example of a plasma processing apparatus suitable for implementation of a method for forming a silicon nitride film of the present invention.

FIG. 11 shows a structure of a planar antenna member.

FIG. 12 shows a configuration of a control unit.

FIG. 13 presents a schematic view of a nonvolatile semiconductor memory device in accordance with a second embodiment of the present invention.

FIG. 14 represents a schematic view of a modification of the nonvolatile semiconductor memory device in accordance with the second embodiment of the present invention.

### DETAILED DESCRIPTION OF EMBODIMENTS

### First Embodiment

Hereinafter, embodiments of the present invention will be described in detail with reference to the accompanying drawings. First of all, a nonvolatile memory device in accordance with an embodiment of the present invention will be described. A nonvolatile semiconductor memory device 200 enables, e.g., a single memory cell having a single transistor to write and read 2-bit or multi-bit information. The nonvolatile semiconductor memory device 200 includes a trench 203 having, e.g., a flask-shaped cross section with a round bottom, which is obtained by forming a groove on a p-type silicon substrate (Si substrate) 201 as a silicon layer; a tunnel oxide film 205 as a first insulating film formed on a surface of the Si substrate 201 which includes inner walls of the trench 203; silicon nitride films 207a and 207b as charge trapping regions provided on a surface of the tunnel oxide film 205 in the trench 203; a silicon dioxide film 209 as a second insulating film for covering the tunnel oxide film 205 and the silicon nitride films 207a and 207b; a gate electrode 211 being in contact with the silicon dioxide film 209 and having a lower portion inserted into the trench 203; and a first source/drain region 213a and a second source/drain region 213b formed in the Si substrate 201 on the opposite sides of the trench 203 to have the trench 203 therebetween.

Moreover, the nonvolatile semiconductor device memory device 200 may also be formed on a P-well or a P-type silicon layer in the Si substrate 201. Furthermore, although it is not illustrated, an isolation film is formed on the Si substrate 201. An active region A where the nonvolatile semiconductor memory device 200 is formed is defined by the isolation film.

The trench 203 has a flat wall portion 203a in which sidewalls facing each other are formed in a substantially flat surface shape from the surface of the Si substrate 201 to a predetermined depth; and a round wall portion 203b connected to the flat wall portion 203a, the round wall portion 203b having opposite sidewalls near the bottom thereof and being expanded (swollen) from the flat wall portion 203a in a horizontal direction (direction perpendicular to a depth direction of the trench 203).

The tunnel oxide film 205 serving as the first insulating film is formed on the top surface of the Si substrate 201 and the inner walls of the trench 203. The tunnel oxide film 205 can be formed by oxidizing a silicon-exposed surface of the Si substrate 201 to a predetermined film thickness by, e.g., a thermal oxidation method or a plasma oxidation method. The tunnel oxide film 205 is a silicon dioxide (SiO₂) film or a silicon oxynitride (SiON) film having a film thickness of, e.g., about 0.1 to 10 nm.

The silicon nitride (SiₓN_{y}) films 207a and 207b as charge trapping regions are provided in pair at the left and right sides in the round wall portion 203b of the trench 203. In other words, the silicon nitride films 207a and 207b are separately formed at the first source/drain region 213a side and the second source/drain region 213b side, respectively, to have the lower portion 211b of the gate electrode 211 therebetween. The silicon nitride films 207a and 207b are disposed between the tunnel oxide film 205 and the silicon dioxide film 209. The silicon nitride films 207a and 207b are an SiₓN_{y} film or a SiON film formed with a film thickness of, e.g., about 2 to 10 nm, in a transverse direction to the lower portion 211b of the gate electrode 211 inserted into the Si substrate 201. Further, the silicon nitride films 207a and 207b preferably have a trap density of, e.g., about 5×10¹² to 1×10¹³ cm⁻²eV⁻¹. The silicon nitride films 207a and 207b can be formed by a plasma CVD (Chemical Vapor Deposition) method using a plasma processing apparatus for generating a plasma by introducing a microwave into a processing chamber by a planar antenna having a plurality of openings. The method for forming the silicon nitride films 207a and 207b will be described in detail later.

The silicon dioxide film 209 as the second insulating film is inserted between the tunnel oxide film 205 or the silicon nitride films 207a and 207b and the lower portion 211b of the gate electrode 211. The silicon dioxide film 209 is formed by, e.g., a CVD method, especially by a thermal CVD method, and serves as a block layer (barrier layer) between the gate electrode 211 and the silicon nitride film 207a and 207b. The silicon dioxide film 209 has a film thickness of, e.g., about 5 to 15 nm. Moreover, a silicon oxynitride film obtained by nitriding the silicon dioxide film 209 can be used as the second insulating film.

The gate electrode 211 has a substantially T-shape when seen from a cross section. An upper portion thereof 211a protrudes from the top surface of the Si substrate 201, and a lower portion thereof 211b is inserted into the trench 203 so as to be in contact with the silicon dioxide film 209. The gate electrode 211 is formed of a polycrystalline silicon film formed by, e.g., a CVD method, and serves as a control gate CG. Moreover, the gate electrode 211 may be formed of a film containing metal, e.g., W, Ti, Ta, Cu, Al, Au, Pt or the like. The upper portion 211a of the gate electrode 211 has a film thickness of, e.g., about 0.1 to 50 nm. Further, the lower portion 211b of the gate electrode 211 has a width of, e.g., about 2 to 10 nm, in a transverse direction.

The gate electrode 211 is not limited to a single layer structure, and may have a laminated structure including, e.g., tungsten, molybdenum, tantalum, titanium, copper, gold, silver, platinum, or silicide, nitride or alloy thereof, in order to decrease resistivity of the gate electrode and increase the operating speed. The gate electrode 211 is connected to a wiring layer (not shown).

The first source/drain region 213a and the second source/drain region 213b have a same conductivity type and are ion-implanted with impurities so that they have the conductivity type different from that of the Si substrate 201. The first source/drain region 213a and the second source/drain region 213b are formed on the Si substrate 201 to have the gate electrode 211 therebetween. The first source/drain region 213a and the second source/drain region 213b have functions of a source and a drain. When one serves as a source, the other serves as a drain.

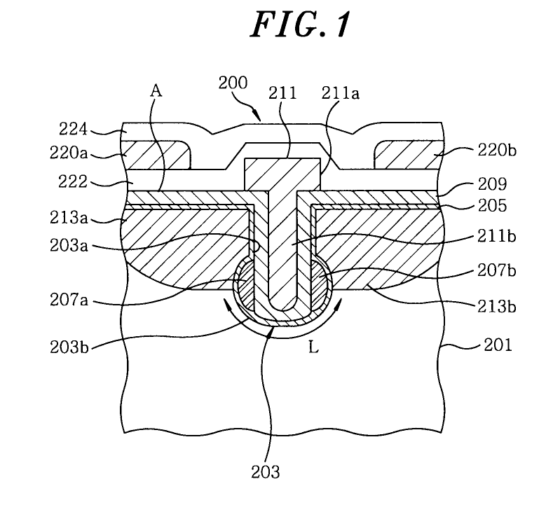

Further, the region around the trench 203 disposed between the first source/drain region 213a and the second source/drain region 213b becomes a channel forming region of the nonvolatile semiconductor memory device 200. The first source/drain region 213a and the second source/drain region 213b are connected to a first source/drain electrode (hereinafter, referred to as a “first electrode”) 220a and a second source/drain electrode (hereinafter referred to as a “second electrode”) 220b via contact holes (not shown), respectively. As illustrated in FIG. 1, the first and the second electrode 220a and 220b are insulated from the gate electrode 211 by a third insulating film 222. A reference numeral “224” indicates a fourth insulating film which protects the first and the second electrode 220a and 220b or separates them from a wiring layer (not shown).

As described above, the nonvolatile semiconductor memory device 200 of the present embodiment has a SONOS structure or an MONOS structure in which the gate electrode 211, the silicon dioxide film 209, the silicon nitride films 207a and 207b, the tunnel oxide film 205 and the Si substrate 201 are arranged in a transverse direction perpendicular to the lower portion 211b of the gate electrode 211 inserted into the trench 203. The SONOS structure and the MONOS structure are formed symmetrically with respect to the lower portion 211b of the gate electrode 211.

Moreover, a channel of the nonvolatile semiconductor memory device 200 is formed with a curvature along the round wall portion 203b of the trench 203 between the first source/drain region 213a and the second source/drain region 213b. Thus, a sufficient channel length L can be ensured without increasing an area of the nonvolatile semiconductor memory device 200.

The following is description of an operation example of the nonvolatile semiconductor memory device 200 configured as described above. The nonvolatile semiconductor memory device 200 enables a single memory cell to write and read 2-bit or multi-bit information as well as 1-bit information by using the pair of silicon nitride films 207a and 207b as charge trapping regions.

The writing, reading and erasing of information in the nonvolatile semiconductor memory device 200 can be performed in a known method, for example, in the sequence disclosed in Japanese Patent Application Publication No. 2001-512290 (Patent Document 1). First, a write voltage VW1 is applied to the gate electrode 211, and a write voltage VW2 is applied to the first source/drain region 213a via the first electrode 220a. The second source/drain region 213b is grounded via the second electrode 220b. Accordingly, charges are trapped in the silicon nitride film 207a adjacent to the first source/drain region 213a due to a hot electron implantation phenomenon, thereby writing 1-bit information.

On the contrary, a write voltage VW3 is applied to the gate electrode 211, and a write voltage VW4 is applied to the second source/drain region 213b via the second electrode 220b. The first source/drain region 213a is grounded via the first electrode 220a. Hence, charges are trapped in the silicon nitride film 207b due to the hot electron implantation phenomenon, thus writing 1-bit information.

In the above writing operation, the write voltages VW1 to VW4 are preferably set to be about ½ of a Vdd (power voltage) so that the probability of generation of hot carriers can increase.

The reading of 1-bit information from the silicon nitride film 207a is performed in a reverse direction of the writing direction. In other words, a read voltage VR1 is applied to the gate electrode 211, a read voltage VR2 is applied to the second source/drain region 213b. The first source/drain region 213a is grounded, and the presence of current flowing from the second source/drain region 213b to the first source/drain region 213a is detected.

Moreover, the reading of 1-bit information from the silicon nitride film 207b is also performed in a reverse direction of the writing direction. In other words, a read voltage VR3 is applied to the gate electrode 211, a read voltage VR4 is applied to the first source/drain region 213a. The second source/drain region 213b is grounded, and the presence of current flowing from the first source/drain region 213a to the second source/drain region 213b is detected.

In the nonvolatile semiconductor memory device 200, the write voltages VW1 to VW4, the read voltages VR1 to VR4, and a threshold voltage for reading may be set so that unintended writing or forward direction reading can be prevented when desired writing or reading is carried out.

In order to erase the 1-bit information from the silicon nitride film 207a, the electrons therein need to be discharged from the gate electrode 211 after passing through the silicon dioxide film 209 or need to be discharged from the first source/drain region 213a after passing through the tunnel oxide film 205 by the tunnel effect. To do so, a positive voltage and a zero voltage (ground potential) may be applied to the gate electrode 211 and the first source/drain region 213a, respectively. Alternatively, a negative voltage for erasing and a positive voltage for erasing may be applied to the gate electrode 211 and the first source/drain region 213a, respectively.

In order to erase the 1-bit information from the silicon nitride film 207b, the electrons 207b therein need to be discharged from the gate electrode 211 after passing through the silicon dioxide film 209 or from the second source/drain region 213b after passing through the tunnel oxide film 205 by the tunnel effect. To do so, a positive voltage and a zero voltage (ground potential) may be applied to the gate electrode 211 and the second source/drain region 213b, respectively. Alternatively, a negative voltage for erasing and a positive voltage for erasing may be applied to the gate electrode 211 and the second source/drain region 213b, respectively.

As described above, the nonvolatile semiconductor memory device 200 of the present embodiment includes the pair of separately provided silicon nitride films 207a and 207b as charge trapping regions, so that it is possible to prevent write failure caused by the short channel effect which was the drawback of the conventional nonvolatile semiconductor memory device. That is, even if the miniaturization is advanced, the charge trapping regions can be distinguished in the nonvolatile semiconductor memory device 200 in the case of writing and reading more than or equal to 2-bit information by a single transistor. Therefore, the nonvolatile semiconductor memory device 200 can store large capacity information with high reliability.

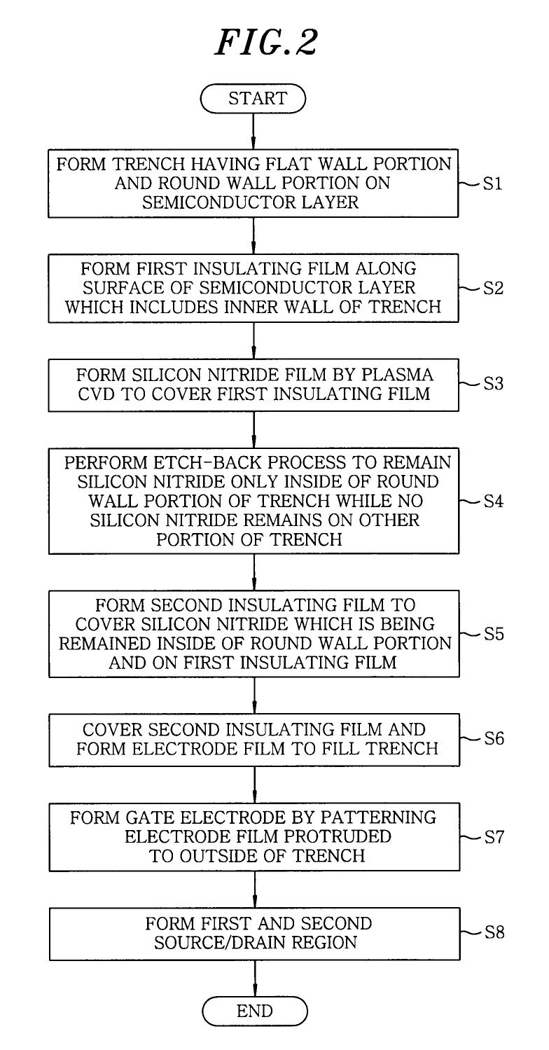

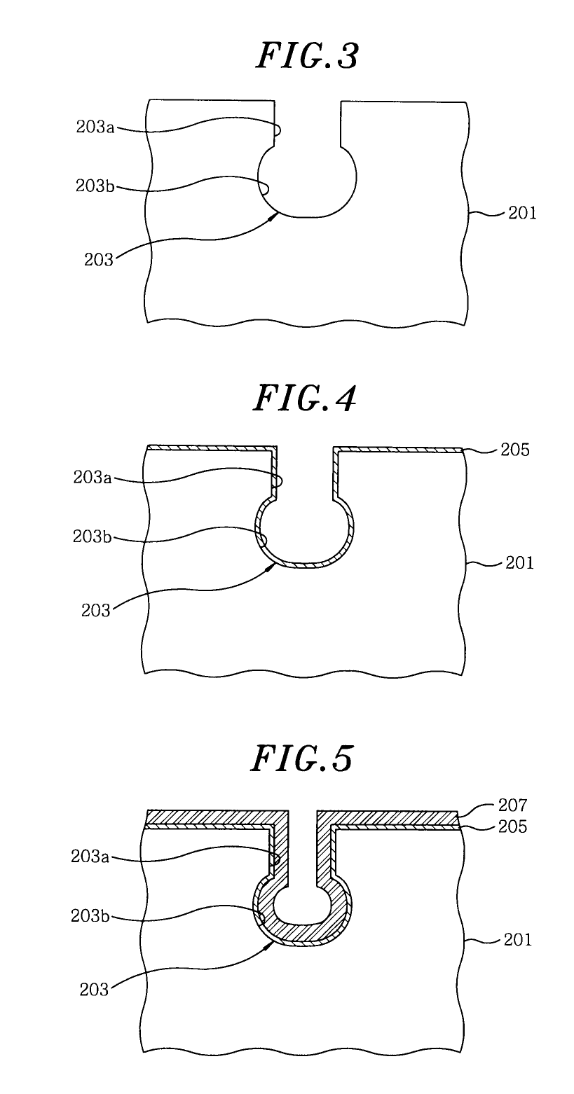

Hereinafter, a method for manufacturing the nonvolatile semiconductor memory device 200 in accordance with the embodiment will be explained with reference to FIGS. 2 to 9. FIG. 2 is a flowchart showing an outline of main processes of the method for manufacturing the nonvolatile semiconductor device memory 200. Further, FIGS. 3 to 9 explain the main processes of the method for manufacturing the nonvolatile semiconductor device memory 200. First, although it is not shown, an isolation film is formed on the Si substrate 201 by, e.g., a LOCOS (Local Oxidation of Silicon) method or an STI (Shallow Trench Isolation) method or the like. Moreover, in order to adjust a threshold voltage of the nonvolatile semiconductor device memory 200, impurities may be doped by ion implantation or the like.

Next, a trench 203 is formed (step S1). As shown in FIG. 3, the trench 203 of the present embodiment has the flat wall portion 203a and the round wall portion 203b. The trench 203 having such cross section can be formed in the manner described in, e.g., Japanese Patent Application Publication No. 2007-88418 (Patent Document 2). Hereinafter, although it is not illustrated, the outline of the processes for forming the trench 203 will be explained. First, the Si substrate 201 is anisotropically etched while using a predetermine mask pattern as an etching mask. Accordingly, a recess which will be an upper portion (flat wall portion 203a) of the trench 203 is formed. Thereafter, a protective film made of a silicon nitride film is formed on the sidewall of the formed recess by, e.g., a CVD method. Since the protective film formed by the CVD method is formed on the entire inner surface of the recess, the protective film formed at the bottom of the recess is removed by the anisotropic etching so that the protective film remains only on the upper portion of the recess which will be referred to as the flat wall portion 203a.

Next, the bottom of the exposed recess is etched by isotropic etching while using the protective film and the mask pattern as an etching mask. Due to the isotropic etching, the Si substrate 201 is etched in a transverse direction inside the recess, so that the lower portion of the recess is formed in a flask shape cross section having a round bottom and is widely swollen compared to the upper portions. In other words, due to the isotropic etching, the side etching is performed near the bottom portion of the recess and, hence, the recess has a configuration that the upper portion of the recess protected by the protective film is protruded inwardly. Further, due to the isotropic etching, the wall portion near the bottom of the recess has a round shape with a curvature, e.g., a spherical shape, an elliptical shape or the like.

The trench 203 thus formed has a shape in which the lower portion 203b near the bottom is expanded in a round shape compared to the upper portion 203a having the wall surfaces substantially perpendicular to the surface of the Si substrate 201. Moreover, the protective film and the mask pattern are removed later.

Next, as shown in FIG. 4, the tunnel oxide film 205 serving as the first insulating film is formed on the upper surface of the Si substrate 201 and the inner wall of the trench 203 by a thermal oxidation method, a plasma oxidation method or the like (step S2). The tunnel oxide film 205 may be formed of a silicon dioxide film, a high-k film or the like. The tunnel oxide film 205 is formed so as to cover the inner wall of the trench 203 and the top surface of the Si substrate 201 in the active region A with a uniform thickness. Furthermore, if necessary, a silicon oxynitride (SiON film) obtained by nitriding the surface of the silicon nitride film 205 may be used as the tunnel oxide film 205. In that case, the nitriding process can be performed by a plasma nitriding method capable of nitriding the surface of the tunnel oxide film at a low temperature. This method can prevent nitrogen from being diffused in the film thickness direction of the tunnel oxide film during the formation of the nitride film.

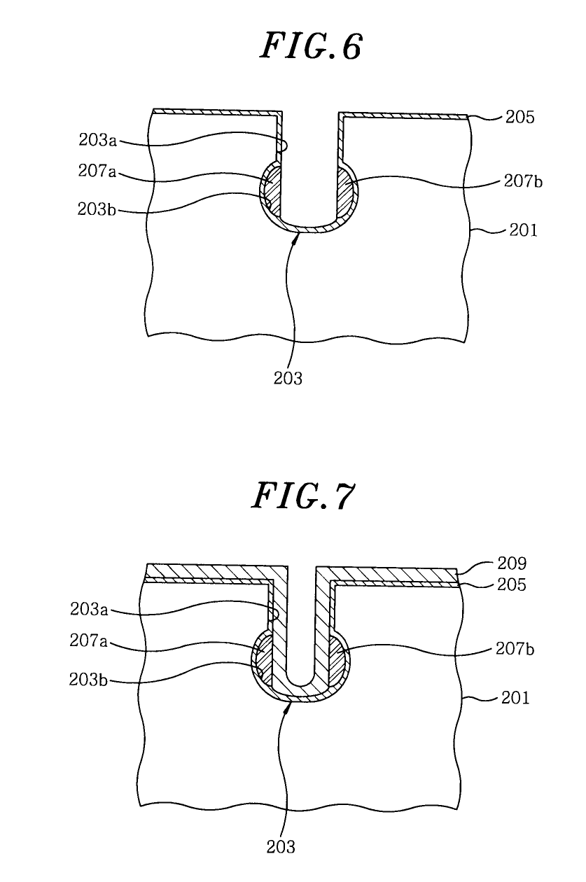

Thereafter, the silicon nitride film 207 is formed so as to cover the surface of the tunnel oxide film 205 by a plasma CVD method (step S3), as illustrated in FIG. 5. The silicon nitride film 207 is formed so as to cover the tunnel oxide film 205 formed on the inside of the trench 203 and the top surface of the Si substrate 201 with a uniform film thickness. The silicon nitride film 207 is preferably formed by using a plasma processing apparatus for generating a plasma by introducing a microwave into a processing chamber by a planar antenna member having, e.g., a plurality of openings. The conditions of the plasma CVD processing for forming the silicon nitride film 207 will be described later.

Then, most of the uniformly formed silicon nitride film 207 is removed by performing an etch-back process (step S4). In the etch-back process, an anisotropic etching is performed, so that the silicon nitride film 207 remains only on the tunnel oxide film 205 formed on the inside of the round wall portion 203b of the trench 203. In this manner, the silicon nitride films 207a and 207b separated from each other 203 on the left side and the right side are formed inside the trench 203, as can be seen from FIG. 6.

Next, as shown in FIG. 7, the silicon dioxide film 209 serving as the second insulating film is formed so as to cover the tunnel oxide film 205 and the silicon nitride films 207a and 207b (step S5).

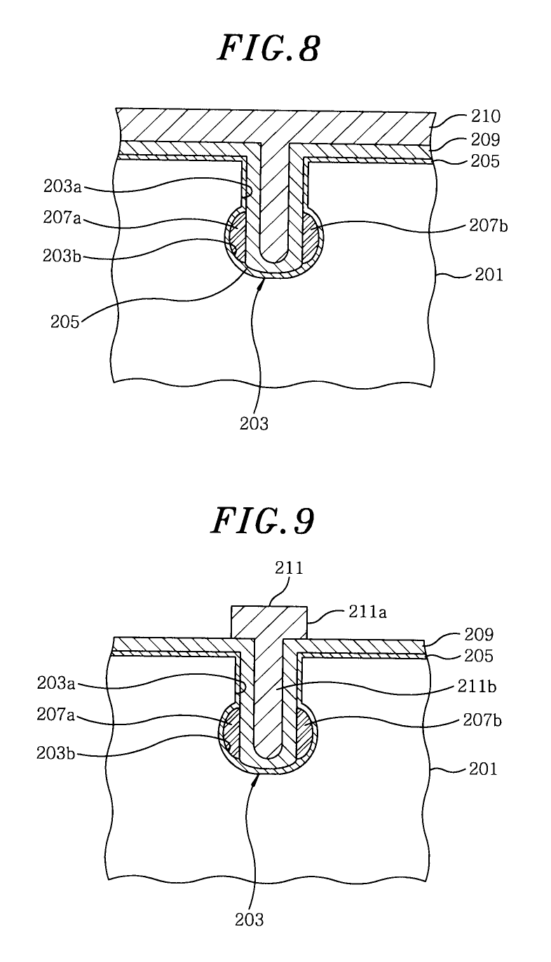

Then, as shown in FIG. 8, an electrode film 210 is formed so as to fill the trench 203 and cover the silicon dioxide film 209 (step S6). The electrode film 210 can be formed by depositing on the silicon dioxide film 209 a polysilicon layer, a metal layer, a metal silicide layer or the like by, e.g., a CVD method or the like.

Next, a pattern is formed by etching the electrode film 210 while using as a mask a resist formed in a pattern by photolithography (step S7). As a consequence, a gate electrode 211 having a substantially T-shape when seen from a cross section is formed. The upper portion 211a of the gate electrode 211 protrudes from the Si substrate 201, and the lower portion 211b is buried in the Si substrate 201.

Thereafter, n-type impurities are ion-implanted into silicon of the active region A at high concentration, so that the first and the second source/drain region 213a and 213b are formed (step S8). Then, the first and the second electrode 220a and 220b are appropriately formed via an interlayer dielectric and, also, a wiring layer is formed. In this manner, the nonvolatile semiconductor memory device 200 having the structure shown in FIG. 1 can be manufactured.

In the above description, although the n-channel type nonvolatile semiconductor memory device apparatus 200 is described as an example, the conductivity type of impurities may be reversed in a p-channel type semiconductor memory device apparatus.

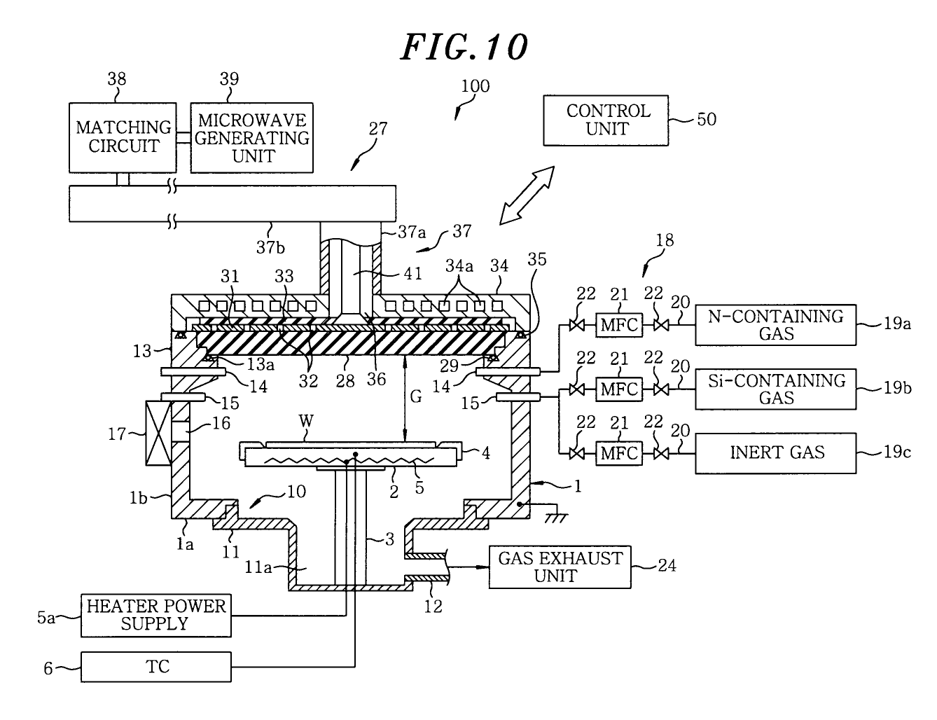

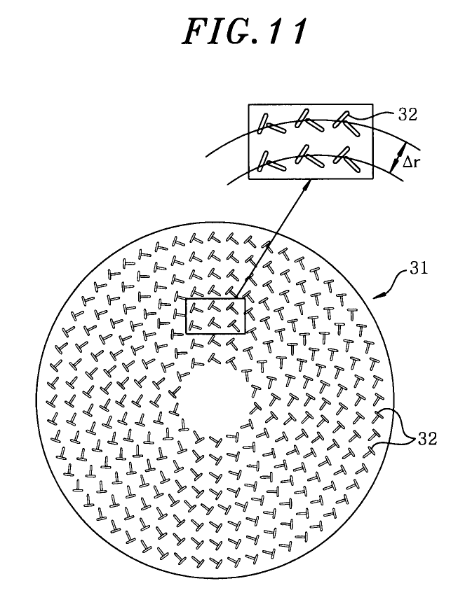

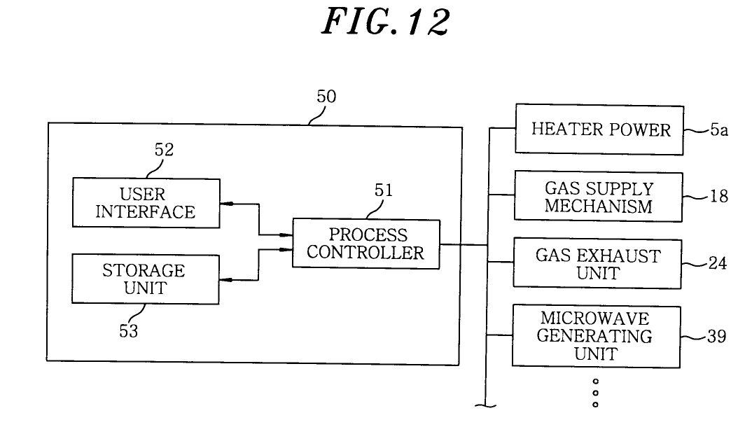

Hereinafter, a method for forming the silicon nitride film 207 as a charge trapping region will be described with reference to FIGS. 10 to 12. FIG. 10 is a cross sectional view schematically showing a configuration of a plasma processing apparatus 100 that can be used to form the silicon nitride films 207a and 207b functioning as charge trapping regions in the present invention. Further, FIG. 11 is a top view of a planar antenna member of the plasma processing apparatus 100. Furthermore, FIG. 12 illustrates a configuration example of a control unit of the plasma processing apparatus 100.

The plasma processing apparatus 100 is configured as an RLSA microwave plasma processing apparatus capable of generating a microwave-exicted plasma of a high density and a low electron temperature by introducing a microwave into a processing chamber from a planar antenna having a plurality of slot-shaped openings, particularly, an RLSA (Radial Line Slot Antenna). The plasma processing apparatus 100 can perform a process using a plasma having a density of 1×10¹⁰ to 5×10¹²/cm³ and an electron temperature of 0.7 to 2 eV. Therefore, the plasma processing apparatus 100 can be suitably used to form a silicon nitride film by a plasma CVD method in the process of manufacturing various semiconductor devices.

The plasma processing apparatus 100 mainly includes an airtight chamber (processing chamber) 1; a gas supply mechanism 18 for supplying gas into the chamber 1; a gas exhaust unit 24 serving as a gas exhaust mechanism for exhausting and depressurizing an inside of the chamber 1; a microwave introducing mechanism 27 provided at an upper portion of the chamber 1, for introducing a microwave into the chamber 1 and; and a control unit 50 for controlling the respective units of the plasma processing apparatus 100.

The chamber 1 is formed by a substantially cylindrical container which is grounded. Further, the chamber 1 may be formed by a square column shaped container. The chamber 1 has a bottom wall 1a and a sidewall 1b made of aluminum or the like.

A mounting table 2 for horizontally supporting a target object to be processed, for example, a silicon wafer W (hereinafter, simply referred to as a “wafer”) is provided in the chamber 1. The mounting table 2 is made of a material having high thermal conductivity such as a ceramic such as AlN or the like. The mounting table 2 is supported by a cylindrical support member 3 extending upwardly from a center of a bottom portion of the gas exhaust chamber 11. The support member 3 is made of, e.g., a ceramic such as AlN or the like.

Further, the mounting table 2 has a cover ring 4 for covering its outer peripheral portion and guiding the wafer W. The cover ring 4 is an annular member made of, e.g., quartz, AlN, Al₂O₃, SiN or the like.

In addition, a resistance heater 5 serving as a temperature control mechanism is buried in the mounting table 2. The heater 5 heats the mounting table 2 by using electric power supplied from a heater power supply 5a, such that the wafer W serving as a target substrate is uniformly heated.

The mounting table 2 is provided with a thermocouple (TC) 6. By measuring the temperature by the thermocouple 6, a heating temperature of the wafer W can be controlled between the room temperature and 900° C.

Further, wafer support pins (not shown) for supporting and vertically moving the wafer W are provided at the mounting table 2. Each of the wafer support pins can be protruded from and retracted into a surface of the mounting table 2.

A circular opening 10 is formed at a substantially central portion of the bottom wall 1a in the chamber 1. A gas exhaust chamber 11 extends downward from the bottom wall 1a and communicates with the opening 10. A gas exhaust pipe 12 is connected to the gas exhaust chamber 11, and the gas exhaust chamber 11 is connected to a gas exhaust unit 24 via the gas exhaust pipe 12.

An annular upper plate 13 is coupled to an upper portion of the sidewall 1b of the chamber 1. A lower inner peripheral portion of the upper plate 13 protrudes inwardly (toward the inner space of the chamber) and thus forms an annular support portion 13a.

An annular gas inlet 14 is provided at the upper plate 13. Further, an annular gas inlet unit 15 is disposed at the sidewall 1b of the chamber 1. In other words, the gas inlets 14 and 15 are arranged in two stages (upper and lower stage) in the vertical direction. Each of the gas inlets 14 and 15 is connected to a gas supply mechanism 18 for supplying a film forming gas or a plasma excitation gas. Moreover, the gas inlets 14 and 15 may be formed in a nozzle shape or a gas shower shape.

In addition, provide on the sidewall 1b of the chamber 1 are a loading/unloading port 16 for loading and unloading the wafer W between the plasma processing apparatus 100 and a transfer chamber (not shown) adjacent thereto, and a gate valve 17 for opening and closing the loading/unloading port 16.

The gas supply mechanism 18 includes, e.g., a nitrogen-containing gas (N-containing gas) supply source 19a, a silicon-containing gas (Si-containing gas) supply source 19b, and an inert gas supply source 19c. The nitrogen-containing gas supply source 19a is connected to the upper gas inlet 14. Further, the silicon-containing gas supply source 19b and the inert gas supply source 19c are connected to the lower gas inlet 15. Furthermore, the gas supply mechanism 18 may have another gas supply source (not shown), e.g., a purge gas supply source used to replace the atmosphere in the chamber, a cleaning gas supply source used to clean the inside of the chamber 1 or the like.

For example, nitrogen gas (N₂), ammonia (NH₃), hydrazine derivative such as MMH (mono methyl hydrazine) or the like can be used for a nitrogen-containing gas as a film forming gas. Moreover, for example, silane (SiH₄), disilane (Si₂H₆), trisilane (Si₃H₈), TSA (trisilylamine), dichlorosilane (SiCl₂H₂) or the like can be used for a silicon-containing gas as another film forming gas. Disilane (Si₂H₆) is especially preferable for the silicon-containing gas. In addition, examples of N₂ gas, rare gas or the like can be used for an inert gas. The rare gas is a plasma excitation gas, and may be, e.g., Ar gas, Kr gas, Xe gas, He gas or the like.

The nitrogen-containing gas is supplied from the nitrogen-containing gas supply source 19a of the gas supply mechanism 18 to the gas inlet 14 via a gas line 20, and then from the gas inlet 14 to the chamber 1. Meanwhile, the silicon-containing gas and the inert gas are supplied from the silicon-containing gas supply source 19b and the inert gas supply source 19c to the gas inlet 15 via the respective gas lines 20, and then from the gas inlet 15 to the chamber 1. Each of the gas lines 20 connected to the gas supply sources is provided with mass flow controller 21 and opening/closing valve 22 disposed at an upstream and a downstream of the mass flow controller 21. With this configuration of the gas supply mechanism 18, it is possible to switch the supplied gas and control a flow rate thereof. Moreover, the rare gas for plasma excitation such as Ar or the like is optional, and may not be supplied simultaneously with the film forming gas.

The gas exhaust unit 24 serving as the gas exhaust mechanism includes a suction mechanism having a high speed vacuum pump. As described above, the gas exhaust unit 24 is connected to the gas exhaust chamber 11 of the chamber 1 via the gas exhaust pipe 12. By operating the gas exhaust unit 24, the gas in the chamber 1 uniformly flows in the space 11a of the gas exhaust chamber 11, and also is discharged from the space 11a to the outside via the gas exhaust pipe 12. Accordingly, the inside of the chamber 1 can be depressurized to, e.g., 0.133 Pa, at a high speed.

Hereinafter, the configuration of the microwave introducing mechanism 27 will be described. The microwave introducing mechanism 27 mainly includes a microwave transmitting plate 28, a planar antenna member 31, a wave retardation member 33, a shield cover 34, a waveguide 37, and a microwave generating unit 39.

The microwave transmitting plate 28 for transmitting a microwave is provided on the support portion 13a protruded from the upper plate 13 toward its inner peripheral portion. The microwave transmitting plate 28 is made of a dielectric material, e.g., quartz or ceramic such as Al₂O₃, AlN or the like. The microwave transmitting plate 28 and the support portion 13a are airtightly sealed via a seal member 29. Therefore, the inside of the chamber 1 is airtightly maintained.

The planar antenna member 31 is provided on the microwave transmitting plate 28 to be opposite the mounting table 2. The planar antenna member 31 is formed in a disc shape. Further, the planar antenna member 31 is not limited to the disc shape but may be of, e.g., a quadrilateral plate shape. The planar antenna member 31 is engaged to the top end of the upper plate 13.

The planar antenna member 31 is made of, e.g., an aluminum plate or a copper plate whose surface is coated with gold or silver. The planar antenna member 31 has a plurality of slot-shaped microwave irradiation holes 32 for radiating a microwave. The microwave irradiation holes 32 are formed through the planar antenna member 31 in a predetermined pattern.

As illustrated in FIG. 11, each of the microwave irradiation holes 32 has a thin and long rectangular shape (slot shape). Further, a pair of microwave irradiation holes 32 is typically arranged in a “T” shape. Furthermore, such pairs of the microwave irradiation holes 32 arranged in a predetermined shape (e.g., T-shape) are arranged along concentric circular lines as a whole.

A length of each of the microwave irradiation holes 32 or an arrangement interval between the microwave irradiation holes 32 are determined by the wavelength (λg) of a microwave. For example, the microwave irradiation holes 32 are arranged to be spaced apart from each other at an interval of λg/4, λg/2, or λg. Further, referring to FIG. 11, a radial distance between the adjacent microwave irradiation holes 32 arranged concentrically is indicated by Δr. Each of the microwave irradiation holes 32 may have a circular shape, an arc shape or the like. Further, the microwave irradiation holes 32 may be arranged in, for example, a spiral shape, a radial shape or the like without being limited to the concentric pattern.

A wave retardation member 33 having a dielectric constant greater than that of vacuum is provided on a top surface of the planar antenna member 31. Since the wavelength of microwaves is increased in a vacuum, the wave retardation member 33 serves to shorten the wavelength of microwaves to thereby control a plasma.

Although there may exist a gap between the planar antenna member 31 and the microwave transmitting plate 28 and between the wave retardation member 33 and the planar antenna member 31, it is preferable that there is no gap therebetween.

A shield lid 34 made of a metal material such as aluminum or stainless steel is formed on the top surface of the chamber 1 to cover the planar antenna member 31 and the wave retardation member 33. The top surface of the upper plate 13 and the shield lid 34 are sealed by a seal member 35. Further, a cooling water path 34a is formed in the shield lid 34. The shield lid 34, the wave retardation member 33, the planar antenna member 31, and the microwave transmitting plate 28 can be cooled by circulating cooling water through the cooling water path 34a. In addition, the shield lid 34 is grounded.

An opening 36 is formed at the center of the upper wall (ceiling portion) of the shield lid 34, and a waveguide 37 is connected to an end of the opening 36. The microwave generating unit 39 for generating microwaves is connected to the other end of the waveguide 37 via a matching circuit 38.

The waveguide 37 includes a coaxial waveguide 37a having a circular cross section and extending upward from the opening 36 of the shield lid 34, and a horizontally-extending rectangular waveguide 37b connected to the upper end portion of the coaxial waveguide 37a.

An internal conductor 41 extends in the center of the coaxial waveguide 37a. The lower end portion of the internal conductor 41 is connected and fixed to the center of the planar antenna member 31. This allows the microwaves to be efficiently and uniformly propagated to the planar antenna member 31 radially through the internal conductor 41 in the coaxial waveguide 37a.

With the above-described configuration of the microwave introducing mechanism 27, a microwave generated by the microwave generation device 39 is transmitted to the planar antenna member 31 via the waveguide 37, and then are introduced into the chamber 1 via the microwave transmitting plate 28. Further, a frequency of, e.g., 2.45 GHz is preferably employed for a frequency of the microwave, however, 8.35 GHz, 1.98 GHz or the like may also be employed.

Each component in the plasma processing apparatus 100 is connected to and controlled by a control unit 50. As shown in FIG. 12, the control unit 50 includes a process controller 51 having a CPU, a user interface 52 and a storage unit 53 connected to the process controller 51. The process controller 51 controls each component of the plasma processing apparatus 100 (e.g., the heater power supply 5a, the gas supply mechanism 18, the gas exhaust unit 24, the microwave generating unit 39 and the like) which is related to the processing conditions such as a pressure, a temperature, a gas flow rate, a microwave output and the like.

The user interface 52 has a keyboard on which a process operator inputs commands to operate the plasma processing apparatus 100, a display for visually displaying the operation status of the plasma processing apparatus 100 and the like. Further, the storage unit 53 stores therein recipes including control programs (software) for implementing various processes executed by the plasma processing apparatus 100 under the control of the process controller 51, processing condition data and the like.

Moreover, the process controller 51 executes a recipe retrieved from the storage unit 53 in response to instructions inputted from the user interface 52 or the like when necessary, so that a required process is performed by the plasma processing apparatus 100 under the control of the process controller 51. Further, recipes such as the control program, the processing condition data and the like may be stored in a computer-readable storage medium, e.g., a CD-ROM, a hard disk, a flexible disk, a flash memory, a DVD, a Blu-ray disc or the like, or may be transmitted on-line from another device via, e.g., a dedicated line whenever necessary.

In the plasma processing apparatus 100 configured as described above, the plasma CVD process can be carried out without inflicting damages on a underlying film or the like at a relatively low temperature not higher than 800° C., more preferably not higher than 600° C. Further, the plasma processing apparatus 100 realizes excellent plasma uniformity and thus can uniformly process the top surface of the substrate and the inner wall surface of the trench.

In the RLSA-type plasma processing apparatus 100 as configured above, a process for depositing a silicon nitride film on the Si substrate 201 can be performed by a plasma CVD method in accordance with the following procedural sequence.

First, the wafer W is loaded into the chamber 1 through the loading/unloading port 16 by opening the gate valve 17, and then is mounted on the mounting table 2. Then, a nitrogen-containing gas and a silicon-containing gas are introduced at predetermined flow rates from the nitrogen-containing gas supply source 19a and the silicon-containing gas supply source 19b of the gas supply mechanism 18 into the chamber 1 through the gas inlets 14 and 15, respectively, while exhausting and depressurizing the inside of the chamber 1. In this manner, a pressure in the chamber 1 is adjusted to a predetermined level.

Next, the microwave of a predetermined frequency, e.g., 2.45 GHz, generated in the microwave generating unit 39 is transferred to the waveguide 37 via the matching circuit 38. The microwave transferred to the waveguide 37 sequentially passes through the rectangular waveguide 37b and the coaxial waveguide 37a, and then are supplied to the planar antenna member 31 via the internal conductor 41. In other words, the microwave is propagated within the rectangular waveguide 37b toward the planar antenna member 31. Further, the microwave is radiated from the slot-shaped microwave irradiation holes 32 of the planar antenna member 31 to the space above the wafer W in the chamber 1 through the microwave transmitting plate 28. At this time, the output of the microwave may be, e.g., 500 to 3000 W.

An electromagnetic field is formed in the chamber 1 by the microwave radiated from the planar antenna member 31 into the chamber 1 through the microwave transmitting plate 28, to thereby generate a plasma of each of the nitrogen-containing gas and the silicon-containing gas. By radiating the microwave through the plurality of microwave irradiation holes 32 of the planar antenna member 31, the microwave excitation plasma has a high density of about 1×10¹⁰ to 5×10¹²/cm³ and a low electron temperature not higher than about 1.5 eV at the vicinity of the wafer W. The microwave excitation high density plasma thus generated inflicts less damage due to ions and the like to the underlying film. Moreover, the source gas is dissociated in the plasma to produce active species such as SiₚH_{q}, SiG_{q}, NH_{q}, N or the like (here and in the following, p and q denote arbitrary numbers), and the active species react to deposit a thin film of silicon nitride SiₓN_{y} (x and y are not necessarily determined based on stoichiometry and have different values according to conditions).

In the present embodiment, the trap density of the silicon nitride films 207a and 207b can be controlled to a desired level by varying the plasma CVD processing conditions when forming the silicon nitride films 207a and 207b. For example, in order to increase the trap density (e.g., in a range of 5×10¹² to 1×10¹³ cm⁻²eV⁻¹) in forming the silicon nitride films 207a and 207b, it is preferable to perform the plasma CVD processing under the following conditions. NH₃ gas and Si₂H₆ gas are used as a nitrogen-containing gas and a silicon-containing gas, respectively. A flow rate of NH₃ gas is set to be in a range of 10 to 5000 mL/min(sccm), more preferably in a range of 100 to 2000 mL/min(sccm), and a flow rate of Si₂H₆ gas is set to be in a range of 0.5 to 100 mL/min(sccm), and more preferably about in a range of 1 to 50 mL/min(sccm). At this time, a flow rate ratio between NH₃ gas and Si₂H₆ gas (NH₃ gas flow rate/Si₂H₆ gas flow rate) is preferably in a range of 0.1 to 1000 in order to form the silicon nitride films 207a and 207b having a high Si density. In addition, when NH₃ gas and Si₂H₆ gas are used, a processing pressure is preferably in a range of 1 to 1333 Pa, and more preferably in a range of 50 to 650 Pa, in order to form the silicon nitride films 207a and 207b having a high trap density.

For example, in order to decrease the trap density (e.g., in a range lower than a range of 5×10¹⁰ to 5×10¹² cm⁻²eV⁻¹) of the silicon nitride films 207a and 207b to be formed, it is preferable to use N₂ gas as a nitrogen-containing gas and Si₂H₆ gas as a silicon-containing gas. To be specific, a flow rate of N₂ gas is set to be in a range of 10 to 5000 mL/min(sccm), more preferably in a range of 100 to 2000 mL/min(sccm), and a flow rate of Si₂H₆ gas is set to be in a range of 0.5 to 100 mL/min(sccm), and more preferably in a range of 0.5 to 10 mL/min(sccm). At this time, a flow rate ratio between N₂ gas and Si₂H₆ gas (N₂ gas flow rate/Si₂H₆ gas flow rate) is preferably in a range of 0.1 to 5000 in order to form the silicon nitride films 207a and 207b with a low Si density to have a uniform film thickness. Further, when N₂ gas and Si₂H₆ gas are used, a processing pressure is preferably in a range of 0.1 to 500 Pa, and more preferably in a range of 1 to 100 Pa, in order to form the silicon nitride films 207a and 207b having a low trap density.

Moreover, silicon nitride films having different trap densities can be alternately deposited by performing the plasma CVD processing while alternating the conditions for increasing the trap density and the conditions for decreasing the trap density.

In any cases, as for a processing temperature of the plasma CVD process, the mounting table 2 is preferably heated to a temperature of 300° C. or higher, and more preferably to a temperature of 400 to 600° C. Further, the gap (between the bottom surface of the microwave transmitting plate 28 and the top surface of the mounting table 2) G in the plasma processing apparatus 100 is preferably set to, e.g., 50 to 500 mm, in order to form the silicon nitride film 207 with a uniform film thickness and a uniform film quality.

Therefore, the nonvolatile semiconductor memory device 200 having the silicon nitride films 207a and 207b as a pair of charge trapping regions can be easily manufactured.

### Second Embodiment

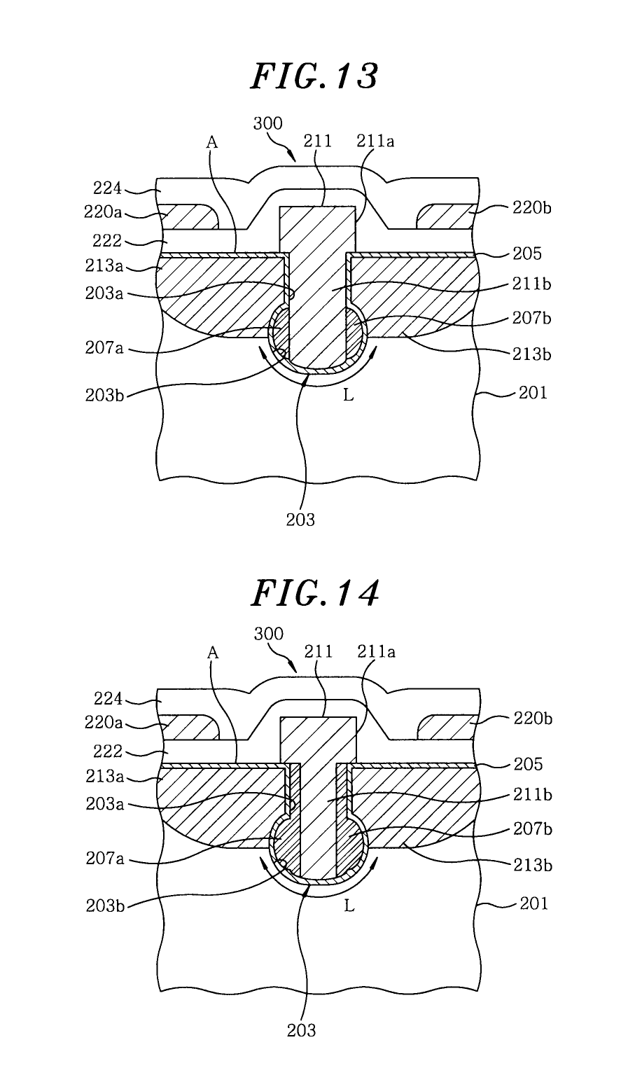

Hereinafter, a semiconductor memory device in accordance with a second embodiment of the present invention will be explained with reference to FIGS. 13 and 14. In the first embodiment, the nonvolatile semiconductor memory device 200 having a SONOS structure or a MONOS structure has been described as an example of the present invention. However, the present invention can also be applied to a nonvolatile semiconductor memory device having an MNOS (Metal-Nitride-Oxide-Silicon) structure.

FIG. 13 is a cross sectional view showing a schematic configuration of the nonvolatile semiconductor memory device in accordance with the second embodiment. A nonvolatile semiconductor memory device 300 of the present embodiment includes a trench 203 obtained by forming a groove on a p-type silicon substrate (Si substrate) 201 as a silicon layer; a tunnel oxide film 205 as a first insulating film formed on a surface of the Si substrate 201 which includes inner walls of the trench 203; silicon nitride films 207a and 207b serving as charge trapping regions formed on the inside of the trench 203; a gate electrode 211 being in contact with the tunnel oxide film 205 and the silicon nitride films 207a and 207b and having a lower portion inserted into the trench 203; and a first source/drain region 213a and a second source/drain region 213b formed in the Si substrate 201 to have the gate electrode 211 therebetween. The silicon nitride films 207a and 207b of the present embodiment preferably have a high trap density, e.g., in a range of 5×10¹² to 1×10¹³ cm⁻²eV⁻¹.

The nonvolatile semiconductor memory device 300 of the present embodiment has an MNOS structure in which the gate electrode 211, the silicon nitride films 207a and 207b, the tunnel oxide film 205 and the Si substrate 201 are arranged in a transverse direction perpendicular to the lower portion 211b of the gate electrode 211 inserted into the trench 203. The MNOS structure is formed symmetrically with respect to the lower portion 211b of the gate electrode 211. Further, the nonvolatile semiconductor memory device 300 enables a single memory cell to write and read 2-bit or multi-bit information as well as 1-bit information by using the pair of silicon nitride films 207a and 207b serving as charge trapping regions.

The nonvolatile semiconductor memory device 300 of the present embodiment is the same as that of the first embodiment except that the silicon dioxide film 209 (the second insulating film, i.e., the upper oxide film) in the nonvolatile semiconductor memory device 200 of the first embodiment shown in FIG. 1 is not provided. Thus, like reference numerals will be given to like parts, and the description thereof will be omitted. Further, writing, reading and erasing in the nonvolatile semiconductor memory device 300 of the present embodiment can be performed in the manner described in the first embodiment. Besides, the nonvolatile semiconductor memory device 300 can be manufactured in the manner described in the first embodiment except that the process for forming the silicon oxide film 209 is not provided. Other configurations, operation and effects of the present embodiment are the same as those of the first embodiment.

In addition, FIG. 14 shows a modification of the nonvolatile semiconductor memory device 300 of the present embodiment. In the present embodiment, as illustrated in FIG. 14, the upper portion of the pair of the silicon nitride films 207a and 207b as the charge trapping regions may be extended along the tunnel oxide film 205 to the position corresponding to the flat wall portion 203a of the trench 203. In this case, when performing the anisotropic etching (etch-back process) of the silicon nitride film 207 in step S4 in the first embodiment, the silicon nitride film 207 may remain near an opening of the trench 203 by stopping the etching in the course thereof, or by performing the etching after providing a mask on the silicon nitride film 207 near the opening of the trench 203. Accordingly, the nonvolatile semiconductor memory device configured as described above can be manufactured. Other configurations of the modification shown in FIG. 14 are the same as those in the second embodiment shown in FIG. 13. Thus, like reference numeral will be given to like parts, and the description thereof will be omitted.

Although the embodiments of the present invention have been described, the present invention may be variously modified without being limited to the above embodiments. For example, although in the above embodiments, the silicon nitride films 207a and 207b are formed by performing etch-back process on the silicon nitride film 207 of a single layer structure, the silicon nitride films 207a and 207b of a laminated structure in which a plurality of silicon nitride thin films are laminated in a transverse direction perpendicular to the depth direction of the trench 203 can be formed by sequentially depositing a plurality of silicon nitride thin films and performing an etch-back process thereafter. In that case, the silicon nitride films 207a and 207b can be formed by a plurality of silicon nitride thin films, each having a trap density different from that of an adjacent silicon nitride thin film, by varying the plasma CVD processing conditions when forming each of the silicon nitride thin films.

Moreover, when the semiconductor device such as the nonvolatile semiconductor memory device or the like is manufactured, a plurality of film forming apparatuses including the plasma processing apparatus 100 are connected to each other through a vacuum state without being exposed to the atmosphere. Therefore, desired films can be sequentially formed in the respective film forming apparatuses. For example, a silicon nitride film having a low trap density and a silicon nitride film having a high trap density can be laminated on the tunnel oxide film in that order or vise versa during at least one cycle.

What is claimed is:

1. A semiconductor memory device comprising:
a semiconductor layer;
a trench formed on the semiconductor layer, the trench including a round wall portion having opposite sidewalls with a curvature;
a first insulating film formed along a surface of the semiconductor layer which includes an inner wall of the trench;
a pair of separately provided charge trapping regions disposed at the round wall portion of the trench to be adjacent to the first insulating film;
a gate electrode having a lower portion inserted into the trench of the semiconductor layer; and
a first and a second region arranged in the semiconductor layer to have the gate electrode interposed therebetween, the first and the second region having a conductivity type different from a conductivity type of the semiconductor layer.

2. The semiconductor memory device of claim 1, further comprising a second insulating layer formed between the gate electrode and the first insulating layer, and between the gate electrode and each of the charge trapping regions.

3. The semiconductor memory device of claim 1, wherein each of the charge trapping regions extends upwardly from the round wall portion of the trench.

4. The semiconductor memory device of any one of claims 1 to 3, wherein each of the charge trapping regions is formed of silicon nitride film.

5. The semiconductor memory device of claim 1, wherein the gate electrode is made of a metal, each of the charge trapping regions is formed of a silicon nitride film, the first insulating film is formed of a silicon dioxide film or a silicon oxynitride film, and the semiconductor layer is made of a silicon, thereby having an MNOS structure in a transverse direction to the gate electrode inserted into the semiconductor layer.

6. The semiconductor memory device of claim 5, wherein the MNOS structure is formed symmetrically with respect to the gate electrode.

7. The semiconductor memory device of claim 2, wherein the gate electrode is made of polycrystalline silicon or a metal, the second insulating film is formed of a silicon dioxide film or a silicon oxynitride film, each of the charge trapping regions is formed of a silicon nitride film, the first insulating film is formed of a silicon dioxide film or a silicon oxynitride film, and the semiconductor layer is made of a silicon, thereby having a SONOS structure or a MONOS structure in a transverse direction to the gate electrode inserted into the semiconductor layer.

8. The semiconductor memory device of claim 7, wherein the SONOS structure or the MONOS structure is formed symmetrically with respect to the gate electrode.

9. The semiconductor memory device of claim 1, wherein the first insulating film is a tunnel oxide film.

10. A semiconductor memory device comprising:
a semiconductor layer;
a gate electrode having an upper portion protruded from the semiconductor layer and a lower portion inserted into the semiconductor layer;
a first insulating film formed along a surface of the semiconductor layer between the semiconductor layer and the gate electrode;
a pair of separately provided charge trapping regions disposed between the first insulating film and the gate electrode; and
a first and a second source/drain region arranged in the semiconductor layer to have the gate electrode interposed therebetween.

11. The semiconductor memory device of claim 10, further comprising a second insulating layer formed between the gate electrode and the first insulating layer, and between the gate electrode and each of and the charge trapping regions.

12. The semiconductor memory device of claim 5, wherein the silicon nitride film is formed by using a plasma processing apparatus for generating a plasma by introducing a microwave into a processing chamber by way of a planar antenna member having a plurality of holes and by using a plasma CVD method for depositing a silicon nitride film by supplying a source gas containing a silicon-containing compound and a nitrogen-containing compound into the processing chamber and generating a plasma by the microwave.

13. A method for manufacturing a semiconductor memory device comprising:
forming on a semiconductor layer a trench including a round wall portion having opposite sidewalls with a curvature;
forming a first insulating film on a surface of the semiconductor layer which includes an inner surface of the trench;
forming a silicon nitride film to cover the first insulating film by a plasma CVD method;
etching the silicon nitride film to remove the silicon nitride film formed at a bottom portion of the trench while leaving a pair of separate silicon nitride films on sidewall portions of the trench which include an inside of the round wall portion;
forming an electrode film to fill the trench;
forming a gate electrode by patterning the electrode film protruded to the outside of the trench; and
forming at both sides of the trench formed on the semiconductor layer a first and a second source/drain region having a conductivity type different from a conductivity type of the semiconductor layer due to impurities doped thereinto.

14. The method of claim 13, wherein in said etching the silicon nitride film, only a pair of separate silicon nitride films remains on the inside of the round wall portion and the silicon nitride film formed on the other portions is removed.

15. The method of claim 13, further comprising, forming a second insulating film to cover the first insulating film and the silicon nitride film between said etching the silicon nitride film and said forming an electrode film.

16. The method of any one of claims 13 to 15, wherein said forming the silicon nitride film is performed by using a plasma processing apparatus for generating a plasma by introducing a microwave into a processing chamber by way of a planar antenna member having a plurality of holes and by using a plasma CVD method for depositing a silicon nitride film by supplying a source gas containing a silicon-containing compound and a nitrogen-containing compound into the processing chamber and generating a plasma by the microwave.

17. The method of claim 16, wherein the silicon nitride film is formed by using ammonia or nitrogen as the nitrogen-containing compound and silane (SiH₄), disilane (Si₂H₆) or trisilane (Si₃H₈) as the silicon-containing compound.

18. The method of claim 16, wherein the silicon nitride film is formed by generating a plasma by using ammonia as the nitrogen-containing compound and disilane as the silicon-containing compound while setting a flow rate ratio (ammonia flow rate/disilane flow rate) to be in a range of 0.1 to 1000 and a processing pressure to be in a range of 1 to 1333 Pa.

19. The method of claim 16, wherein the silicon nitride film is formed by generating a plasma by using nitrogen as the nitrogen-containing compound and disilane as the silicon-containing compound while setting a flow rate ratio (nitrogen flow rate/disilane flow rate) to be in a range of 0.1 to 5000 and a processing pressure to be in a range of 0.1 to 500 Pa.

20. The method of claim 16, wherein a processing temperature in the plasma CVD method is in a range of 25 to 600° C.
